(19) United States
(12) Patent Application Publication
(10) Pub. No.: US 2006/0171197 A1
(43) Pub. Date: Aug. 3, 2006

(54) Magnetoresistive memory element having a stacked structure

(76) Inventors: Ulrich Klostermann, Fontainebleau (FR); Daniel Braun, Paris (FR)

Correspondence Address: EDELL, SHAPIRO & FINNAN, LLC, 1901 RESEARCH BOULEVARD, SUITE 400, ROCKVILLE, MD, 20850, US

(21) Appl. No.: 11/045,512

(22) Filed: Jan. 31, 2005

(51) Int. Cl. G11C 11/00

(52) U.S. Cl. 365/158

(57) ABSTRACT

A magnetoresistive memory element has a stacked structure including: a tunneling barrier made of non-magnetic material, a first magnetic system with a ferromagnetic tunneling junction reference layer barrier having a fixed magnetic moment vector on one side of the tunneling adjacent to the non-magnetic material, and a second magnetic system with a ferromagnetic tunneling junction free layer on an opposite side of the tunneling barrier having a free magnetic moment vector adjacent to the non-magnetic material and forming a magnetoresistive tunneling junction. The tunneling junction free layer is one of a plurality of N ferromagnetic free layers which are antiferromagnetically coupled. The first magnetic system is sandwiched in between the tunneling junction free layer and at least one of the ferromagnetic free layers that are anti-ferromagnetically coupled therewith.

### FIELD OF THE INVENTION

The present invention relates to non-volatile semiconductor memory chips and, more particularly, to magnetoresistive memory cells (MRAM cells) for use in a semiconductor integrated circuit.

### BACKGROUND

In recent years, great efforts have been made to bring new non-volatile memory technology based on magnetoresistive random access memory cells into commercial use. A magnetoresistive memory cell includes a layered structure of ferromagnetic layers separated by a non-magnetic tunneling barrier and arranged into a magnetic tunnel junction (MTJ). Digital information is not maintained by power, as in conventional DRAMs, but rather by specific directions of the magnetic moment vectors in the ferromagnetic layers. More specifically, in an MRAM cell, magnetization (i.e., the magnetic moment vector) of one ferromagnetic layer (“reference layer”) is magnetically fixed or pinned, while magnetization of the other ferromagnetic layer (“free layer”) can switch between two preferred directions, i.e., the same and opposite directions with respect to the fixed magnetization of the reference layer. Depending upon the magnetic states of the free layer, i.e., parallel or antiparallel states of its magnetization with respect to the magnetization of the reference layer, the magnetic memory cell exhibits two different resistance values in response to a voltage applied across the magnetic tunnel junction barrier. The particular resistance of the memory cell thus reflects the magnetization states of the free layer, wherein the resistance is “low” when the magnetization is parallel, and “high” when the magnetization is antiparallel. Accordingly, detection of changes in resistance allows access to information stored in the magnetic memory element, i.e., read information from the magnetic memory cell.

An MRAM cell is written to by application of magnetic fields created by bi- or uni-directional currents flowing through current lines, typically, bit and/or write word lines, to magnetically align the free layer magnetic moment vector in a parallel or an antiparallel state in relation to the fixed magnetization. If a magnetic field in a direction opposite to the magnetization direction of the free layer is applied, then the magnetic moment vector of the free layer is reversed in case a critical magnetic field value is reached (also referred to as reversal magnetic field). The value of the reversal magnetic field is determined from a minimum energy condition. Assuming that a magnetic field applied to the direction of the hard axis of magnetization is represented by Hₓ and a magnetic field applied to the direction of the easy axis of magnetization is represented by H_{y}, then a relationship Hₓ^{(2/3)}+H_{y}^{(2/3)}=H_{c}^{(2/3)} is established, where H_{c} represents the anisotropic magnetic field of the free layer. Since this curve forms an astroid on an Hₓ-H_{y}-plane, it is called an astroid curve. As can be seen from above relationship, a composite magnetic field enables the selection of a single MRAM-cell in case the sum of both magnetic fields at least amounts to the reversal magnetic field. Based on the above, the “Stoner-Wohlfahrt”-switching scenario is typically used for switching MRAM cells, and is well-known to those skilled in the art, and is not explained in further detail here.

In recent years, magnetoresistive tunneling junction memory cells where the free layer is designed to be a system of ferromagnetic free layers that are antiferromagnetically coupled. The number of antiferromagnetically coupled layers are selected to increase the effective magnetic switching volume of the MRAM device has been described. For the switching of such magnetoresistive memory cells, another switching scenario, i.e., “adiabatic rotational switching,” is typically used. Adiabatic rotational switching relies on the “spin-flop” phenomenon, which lowers the total magnetic energy in an applied magnetic field by rotating the magnetic moment vectors of the antiferromagnetically coupled ferromagnetic free layers. More specifically, assuming that a bit line magnetic field H_{BL} and a word line magnetic field H_{WL}, respectively, arrive at the MRAM cell for its switching, and that antiferromagnetically coupled magnetic moment vectors M₁ and M₂ exhibited by the ferromagnetic free layers are inclined at a 45° angle to the word and bit lines, respectively, a timed switching pulse sequence of applied magnetic fields in a typical “toggling write” mode is as follows:
at time t₀, neither a word line current nor a bit line current are applied resulting in a zero magnetic field H₀ of both H_{BL} and H_{WL};
at time t1, the word line current is increased to H₁ and magnetic moment vectors M₁ and M₂ begin to rotate either clockwise or counter-clockwise, depending on the direction of the word line current;
at time t₂, the bit line current is switched on, where flow in a certain direction is selected so that both magnetic moment vectors M₁ and M₂ are further rotated in the same clockwise or counter-clockwise direction as the rotation caused by the word line magnetic field; both the word and bit line currents are on, resulting in magnetic field H₂ with magnetic moment vectors M₁ and M₂ being nominally orthogonal to the net magnetic field direction, which is 45° with respect to the current lines;
at time t₃, the word line current is switched off, resulting in magnetic field H₃, so that magnetic moment vectors M₁ and M₂ are rotated only by the bit line magnetic field; magnetic moment vectors M₁ and M₂ have generally been rotated past their hard axis instability points; and
finally, at time t₄, the bit line current is switched off, again resulting in zero magnetic field H₀, and magnetic moment vectors M₁, M₂ align along the preferred anisotropy axis (easy axis) in a 180° angle rotated state as compared to the initial state.
   Accordingly, with regard to the magnetic moment vector of the reference layer, the MRAM cell has been switched from its parallel state into its anti-parallel state, or vice versa, depending on the state switching (“toggling”) starts off with. Further, in order to successfully switch an MRAM cell, in a coordinate plane spanned by H_{WL} and H_{BL}, it is a precondition that a magnetic field sequence applied thereon results in a magnetic field path crossing a diagonal line and circling around a critical magnetic field value (“toggling point”) T for initiating toggle switching, since in that case magnetic moment vectors M₁ and M₂ are rotated past their hard axis instability points.

In modern portable equipment, such as portable computers, digital still cameras, and the like, which require large memory performance, one of the most important issues for MRAM cells is to provide high-dense arrays of MRAM cells. However, when scaling down MRAM cells based on antiferromagnetically coupled free layers, coupling of the free layers increases dramatically, thus requiring relatively high spin-flop magnetic fields for switching the cells (i.e., toggling around the toggling point as described above).

FIG. 1 schematically illustrates a typical layered structure of a conventional MRAM element used in an MRAM cell provided with antiferromagnetically coupled ferromagnetic free layers. In such an arrangement, on a metallic base material MA which typically is connected to an active structure of a semiconductor wafer substrate (not shown), there is a reference layer system R, a tunneling barrier B1 made of a non-magnetic material, and a magnetic free layer system having ferromagnetic layer FL1 and ferromagnetic layer FL2 separated by a relatively thick spacer layer S1. In the magnetic free layer system, ferromagnetic free layers FL1, FL2 are antiferromagnetically coupled. Further, an underlayer UL1 below the reference layer system R as well as a cap layer CL1 above the magnetic free layer system are optionally arranged. In more detail in FIG. 2A, a magnetic free system, which has ferromagnetic free layers FL1, FL2 and spacer layer S1, has a height r. As a result of numeric simulations, in FIG. 2B, a relationship between a varied thickness of spacer 6 made of Ru results in a change of magnetic free system height r (where the thickness of free layers FL1, FL2 remains constant). The spin-flop magnetic field (see the lower curve) and the saturation field (upper curve) are shown. Accordingly, decreasing spacer S1 thickness (i.e., decrease height r) results in an increase of both spin-flop and saturation fields. For that reason, thick spacer layers S1 are preferable, yet detrimental to down-scaling memory cells by typically requiring long-lasting etching times and increasing critical dimension loss. However, spacer layer material is selected in view of achieving appropriate etching characteristics, and thus the choice of spacer materials is limited.

A magnetoresistive memory element allowing a memory element size down-scale without thereby causing an increase of the coupling between antiferromagnetically coupled ferromagnetic free layers of the magnetic free system is desirable.

### SUMMARY

A magnetoresistive memory element, which has a stacked structure, includes a tunneling barrier made of a non-magnetic material and first and second magnetic systems. The first magnetic system includes a ferromagnetic tunneling junction reference layer having a fixed magnetic moment vector arranged on one side of the tunneling barrier adjacent the non-magnetic material. The second magnetic system includes a ferromagnetic tunneling junction free layer having a free magnetic moment vector being arranged on an opposite side of the tunneling barrier adjacent the non-magnetic material. The free magnetic moment vector switches between the same and opposite directions with respect to above fixed magnetic moment vector. In the memory element, the tunneling barrier and the tunneling junction free and tunneling junction reference layers arranged on both sides of the barrier together form a magnetoresistive tunneling junction (MTJ). In the memory element of the invention, the tunneling junction free layer is one of a plurality of N ferromagnetic free layers, which are antiferromagnetically coupled, where N is an integer greater than or equal to two.

According to a characteristic feature of the invention, first magnetic system is sandwiched between the tunneling junction free layer and at least one of the ferromagnetic free layers of the second magnetic system that antiferromagnetically coupled therewith. Therefore, the first magnetic system between the antiferromagnetically coupled ferromagnetic free layers and using the a further down-scale of the memory element is possible without the undesired effects on the coupling of antiferromagnetically coupled free layers. In other words, the first magnetic system is used as a “spacer” in between the antiferromagnetically coupled free layers. Furthermore, long etching times and an increased critical dimensional loss can be avoided.

In an exemplary embodiment of the invention, the first magnetic system and the ferromagnetic free layer, that is antiferromagnetically coupled with above tunneling junction free layer, are separated by a first underlayer. The first underlayer is used as a diffusion barrier and seed layer for the stack growth of the first magnetic system. Furthermore, the first underlayer is used as an etch stop layer in case etching of the first magnetic system and the ferromagnetic free layer, which is antiferromagnetically coupled with the tunneling junction free layer, is decoupled.

In another exemplary embodiment of the invention, the ferromagnetic free layer, which is antiferromagnetically coupled with the tunneling junction free layer, is sandwiched between the first underlayer and a second underlayer. The second underlayer is used as a diffusion barrier and seed layer for stack growth of the ferromagnetic free layer, which is antiferromagnetically coupled with the tunneling junction free layer. Each one of the first and second underlayers may have several sublayers, as necessary.

In yet another exemplary embodiment of the invention, the first magnetic system has a first subsystem with the tunneling junction reference layer having a fixed magnetic moment vector and a second subsystem for fixing (pinning) of the fixed magnetic moment vector. Each of above subsystems may include one or a plurality of layers.

In another exemplary embodiment of the invention, in order to a further decrease the spin-flop magnetic switching field(s), a ferromagnetic offset field layer exhibits a magnetic moment vector adapted to shift a toggling point for switching of above free magnetic moment vector towards a smaller spin-flop field. In other words, in a coordinate plane spanned by the magnetic fields arriving at the memory element of orthogonally aligned first and second current lines for switching the element, such as bit and word lines, the magnetic field of such a ferromagnetic offset field layer shifts the toggling point for switching the memory element towards the origin of coordinates. To achieve this effect, the ferromagnetic offset field layer, for instance, exhibits a magnetic moment vector along an easy axis direction of the tunneling junction free layer. The ferromagnetic offset field layer (i.e., first magnetic moment vector) is pinned by the second reference subsystem. Alternatively, there is a further multi-purpose layer system arranged adjacent the ferromagnetic offset field layer.

In yet another exemplary embodiment of the invention, a side wall spacer is arranged around at least a part, or the whole, of the perimeter (peripheral surface) of at least the ferromagnetic tunneling junction free layer. At least surrounding the tunneling junction free layer, the side wall spacer surrounds several or all layers included in the stacked structure of the memory element of the invention. In particular, the ferromagnetic layers of the second magnetic system and the layers laying between the ferromagnetic layers are surrounded. Providing a side wall spacer allows for a linear dimension of the tunneling junction free layer in a direction perpendicular to a stacking direction of the stacked structure, which is less than a linear dimension ferromagnetic free layer which is antiferromagnetically coupled therewith. By this measure, there is a further reduction of dipole coupling between antiferromagnetically coupled ferromagnetic free layers and a further lowered spin-flop magnetic field. Similarly, a linear dimension of the tunneling junction free layer in a direction perpendicular to a stacking direction of the stacked structure is less than a linear dimension of the ferromagnetic offset field layer, and results in a relatively more homogeneous magnetic stray field arriving at the tunneling junction free layer. Apart from enabling different linear dimensions of the layers, especially in structuring the second magnetic system, the side wall spacer forms a “shield” at least around the tunneling junction ferromagnetic free layer and reduces etch damage of the tunneling junction free layer or tunneling barrier due to etch chemistry and undesired precipitates during etching.

### BRIEF DESCRIPTION OF THE DRAWINGS

The accompanying drawings, which are incorporated in and constitute a part of the specification, illustrate presently preferred embodiments of the invention, and together with the general description given above and the detailed description given below, serve to explain the principles of the invention. Embodiments of the present invention will be described in detail below with reference to the accompanying drawings, where like designations denote like elements.

FIG. 1 illustrates schematically a stacked structure of a conventional MRAM element;

FIGS. 2A and 2B show schematically a magnetic free system having antiferromagnetically coupled ferromagnetic layers and a diagram illustrating reduction of spin-flop and saturation magnetic fields in response to a variation of magnetic free system thickness;

FIGS. 3A and 3B illustrate exemplary embodiments of a magnetoresistive memory element of the invention;

FIGS. 4A and 4B illustrate further exemplary embodiments of a magnetoresistive memory element of the invention; and

FIGS. 5A to 5E illustrate yet further exemplary embodiments of a magnetoresistive memory element of the invention.

### DETAILED DESCRIPTION

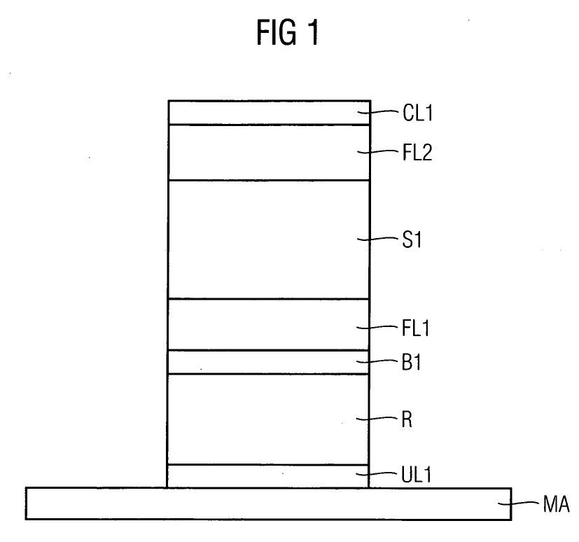

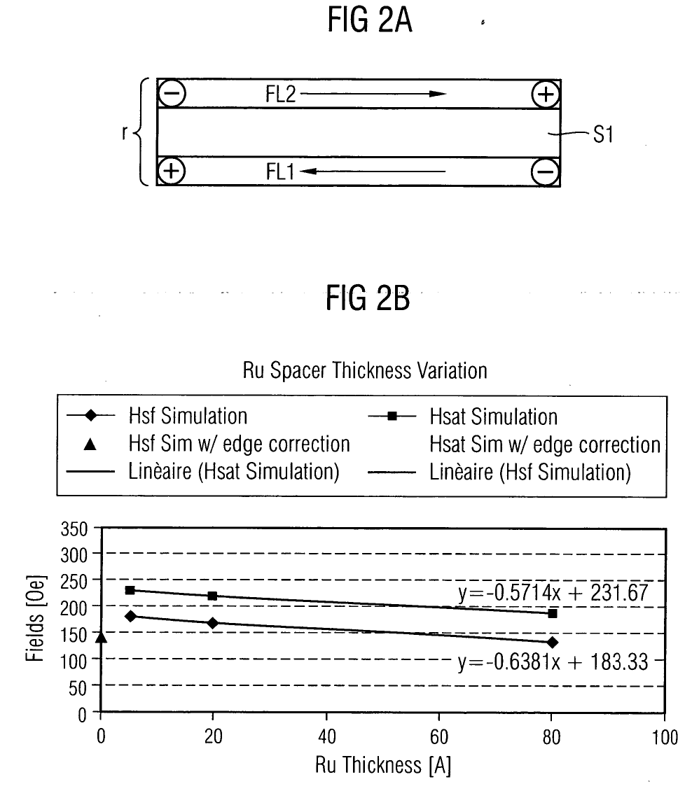

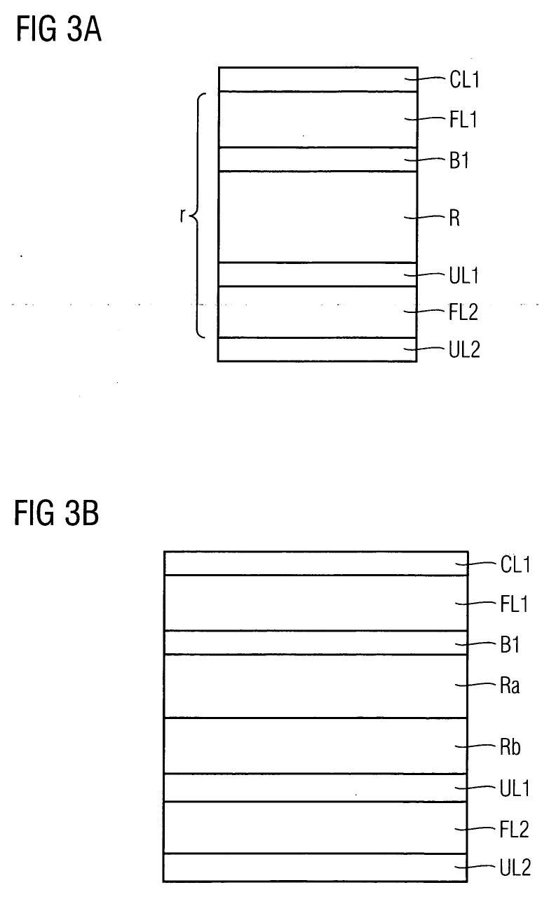

FIGS. 3A and 3B, are schematic cross sectional views sectioned along a stacking direction of the memory element layer stack. Referring to FIG. 3A, there is a tunneling barrier B1 of a non-magnetic material, a first magnetic system R with a ferromagnetic tunneling junction reference layer having a fixed magnetic moment vector on one side of the tunneling barrier B1 adjacent to the non-magnetic material, and a second magnetic system with a ferromagnetic tunneling junction free layer FL1 having a free magnetic moment vector on an opposite side of the tunneling barrier B1 adjacent to the non-magnetic material, which switches between the same and opposite directions with respect to the fixed magnetic moment vector are provided. The tunneling barrier B1 and the tunneling junction free and tunneling junction reference layers together form a magnetoresistive tunneling junction. The tunneling junction free layer FL1 is one of two ferromagnetic free layers FL1, FL2, which are antiferromagnetically coupled. Further, there is a first underlayer UL1 below the second magnetic system. A second underlayer UL2 below the ferromagnetic free layer FL2 the tunneling junction free layer FL1 is antiferromagnetically coupled therewith. Both underlayers UL1, UL2 are used as diffusion barriers and seed layers for the stack growth. A cap layer CL1 is arranged above the ferromagnetic free layer FL1. In FIG. 3A, the second magnetic system R is sandwiched between the tunneling junction free layer FL1 and the other ferromagnetic free layer FL2 of the second magnetic system being antiferromagnetically coupled with tunneling junction free layer FL1. Compared to the conventional memory cell as detailed in FIG. 1, a large distance r between both ferromagnetic free layers FL1, FL2, is possible without an additional spacer layer. The conventional spacer layer rendering superfluous, it is possible to scale-down the memory element can be scaled down without adverse effects on dipole coupling of the ferromagnetic free layers FL1, FL2.

In further embodiments of the invention, differences as to the memory element of FIG. 3A or other memory elements reference are described.

Referring to FIG. 3B, the first magnetic system R is a two-subsystem structure Ra, Rb, where subsystem Ra is antiferromagnetically coupled to subsystem Rb. More particularly, subsystem Ra includes the tunneling junction ferromagnetic free layer, which is pinned by the pinning subsystem Rb. Both subsystems Ra, Rb are sandwiched between ferromagnetic free layers FL1, FL2. In this embodiment, subsystem Ra is for instance, made of a layered structure CoFe/Ru/CoFe (for example, having a thickness of roughly 2/1/3 nm) and subsystem Rb is for instance, made of PtMn. If subsystem Rb is made of PtMn, subsystem Rb is used as an etch stop layer.

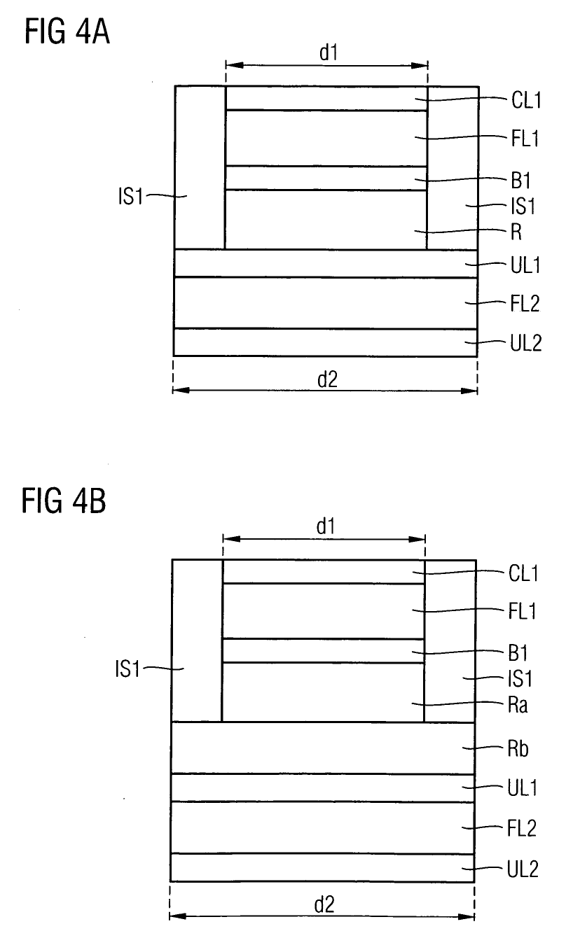

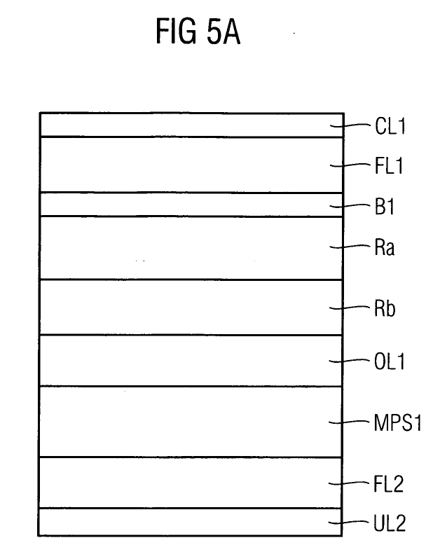

Referring to FIG. 4A, a side wall spacer IS1 is provided around the perimeter of the magnetic tunnel junction. The side wall spacer includes ferromagnetic free layer FL1, tunneling barrier B1, and reference layer R. A variation of the spacer thickness allows the fabrication of different sized ferromagnetic free layers FL1, FL2, where a linear dimension dl perpendicular to a stacking direction of the stacked structure of ferromagnetic free layer FL1 is smaller than the corresponding linear dimension d2 of ferromagnetic free layer FL2 antiferromagnetically coupled with ferromagnetic free layer FL1. Further reduction of the dipole coupling between ferromagnetic free layers FL1 and FL2, and a desired reduction of spin-flop magnetic field are possible. The first underlayer 1 is used as an etch stop layer for the side wall spacer IS1. In further structuring of the memory element, the side wall spacer IS1 is used as a shield surrounding the magnetic tunneling junction and thus avoids etch damage of the tunneling junction free layer FL1 and tunneling barrier B1.

Referring to FIG. 4B, the first magnetic system R is a two-subsystem structure with subsystem Ra and subsystem Rb as described above in FIG. 3B. The subsystem Rb, for instance, is made of PtMn, and is used as an etch stop layer.

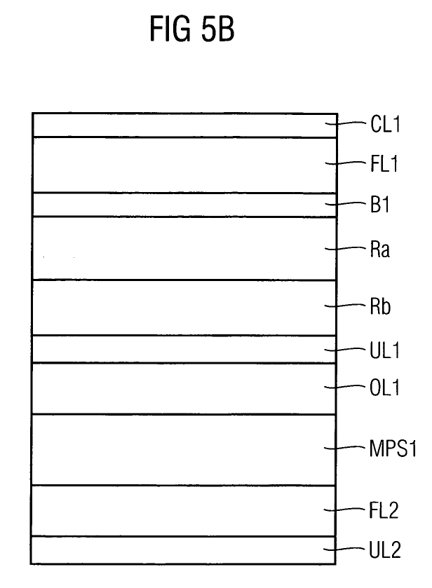

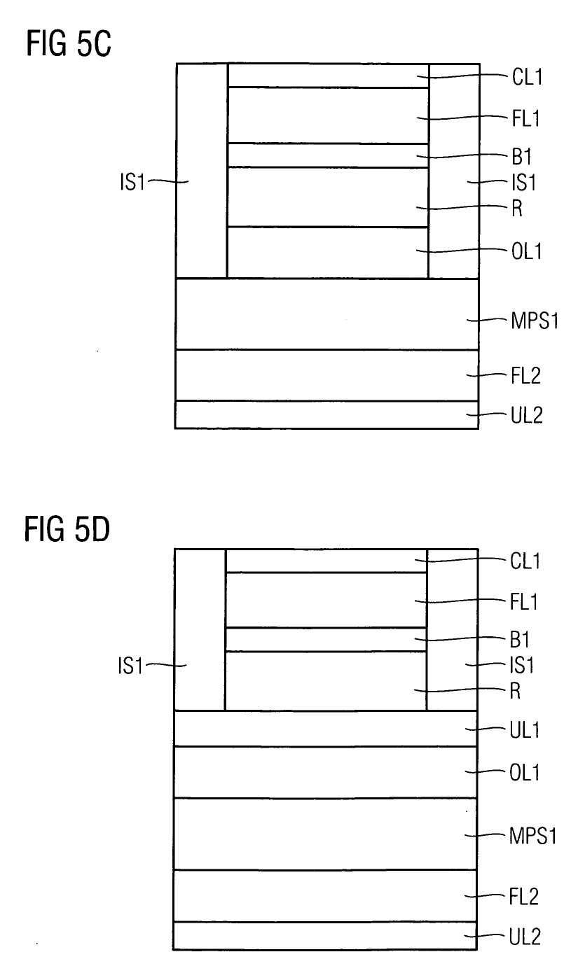

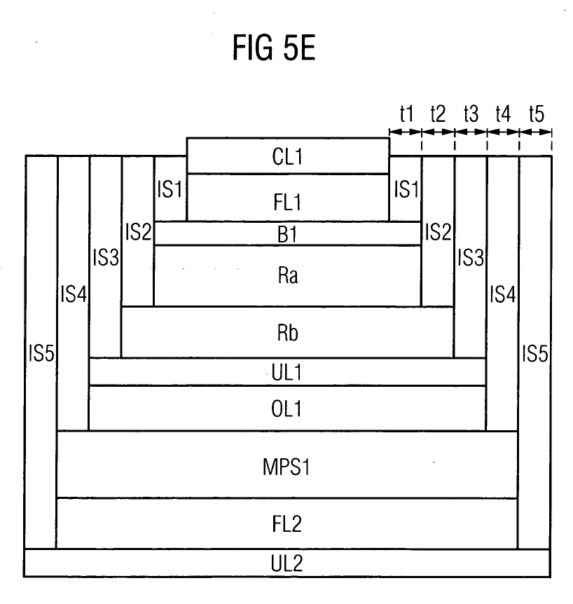

Referring to FIG. 5A, a ferromagnetic offset field layer for reducing the switching fields and a multi-purpose system MPS1 are arranged, without having an underlayer UL1. In the embodiment illustrated in FIG. 5A, the ferromagnetic offset field layer is pinned by the subsystem Rb, while the main function of the MPS1 is to be a seed layer for ferromagnetic offset field layer OL1 and to be a spacer layer for ferromagnetic free layer FL2. Alternatively, the ferromagnetic offset field layer is pinned by the MPS1.

Referring to FIG. 5B, there is a further underlayer UL1 below the second magnetic system, which is a seed layer for growing the first magnetic system, and, is used to achieve a magnetic decoupling of subsystem Rb and the ferromagnetic offset field layer OL1, for example, when the subsystem Rb is made of PtMn. If the subsystem Rb and the ferromagnetic offset field layer OL1 are magnetically decoupled, the ferromagnetic offset field layer OL1 is pinned by the MPS1.

Referring to FIG. 5C, a side wall spacer IS1 surrounds the perimeter of the magnetic tunnel junction. The sidewall spacer includes a ferromagnetic layer FL1, a tunneling barrier B1, a first magnetic system R, a ferromagnetic offset field layer OL1, and a cap layer CL1.

Referring to FIG. 5D, there is a further underlayer UL1 underlying reference layer R, which is a seed layer for growth the first magnetic system R and achieves magnetic decoupling between the first magnetic system R and the ferromagnetic offset field layer OL1. Further, since side wall spacer IS1 does not reach the ferromagnetic offset field layer OL1, a linear dimension of the ferromagnetic offset field layer OL1 in a direction perpendicular to a stacking direction of the stacked structure is larger than that one of the tunneling junction free layer FL1 positioned within the side wall spacer IS1, results in a relatively more homogenous magnetic stray field of the OL1 arriving at the FL1.

FIG. 5E illustrates various sidewall spacers of the present invention in one figure. Starting from the embodiment as shown in FIG. 5D having its second magnetic system R realized as two subsystems Ra and Rb, side wall spacer IS1 reaches the tunneling barrier B1, side wall spacer IS2 reaches the subsystem Rb, side wall spacer IS3 reaches the underlayer UL1, side wall spacer IS4 reaches the MPS1, and side wall spacer IS5 reaches the underlayer UL2. Depending on the specific design of the memory element, different parts of the stacked structure of the memory element of the invention may be appropriately surrounded by the side wall spacer.

In previous embodiments of the memory element of the invention, the ferromagnetic layers FL1, FL2 are, for instance, made of one or more materials selected from NiFe, CoFeB and CoFe/Py, the first and second underlayers UL1, UL2 are, for instance, made of one or more materials selected from TaN/NiFeCr, Ru, Ta, NiFeCr and Ta/TaN/Ru, the ferromagnetic offset field layer OL1 is, for instance, made of one or more materials selected from CoFeB, NiFe and CoFe/Ru/CoFeB, the reference sub layer Ra is, for instance, made of one or more materials selected from Co/CoTb and CoFe/Ru/CoFe/CoFeB, the reference sub layer Rb is, for instance, made of one or more materials selected from PtMn, Ru, TaN/Ta/PtMn and Ru/NiFeCr/PtMn, the multi-purpose system MPS1 may for instance be made of one or more materials selected from Ru, TaN/Ta/PtMn and Ru/NiFeCr/PtMn, the side wall spacer IS1 is, for instance, made of one or more materials selected from SiO₂/SiN and Al₂o₃/SiO₂, and, the tunneling barrier B1 is, for instance, made of one or more materials selected from Al₂O₃, MgO and BN, however, given as examples, there is no limitation to such materials.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A magnetoresistive memory element having a stacked structure, comprising:
a tunneling barrier made of a non-magnetic material;
a first magnetic system including a ferromagnetic tunneling junction reference layer having a fixed magnetic moment vector, the ferromagnetic tunneling junction being arranged on one side of the tunneling barrier adjacent to the non-magnetic material; and
a second magnetic system including a ferromagnetic tunneling junction free layer having a free magnetic moment vector, the ferromagnetic tunneling junction free layer being arranged on an opposite side of the tunneling barrier adjacent to the non-magnetic material which switches between the same and opposite directions with respect to the fixed magnetic moment vector, the tunneling barrier, the tunneling junction free, and the tunneling junction reference layers forming a magnetoresistive tunneling junction, the tunneling junction free layer being one of a plurality of N ferromagnetic free layers which are antiferromagnetically coupled, where N is an integer greater than or equal to two,
wherein the first magnetic system is sandwiched between the tunneling junction free layer and at least one of the ferromagnetic free layers of the second magnetic system being antiferromagnetically coupled therewith.

2. The magnetoresistive memory element of claim 1, wherein the first magnetic system includes a first subsystem having the tunneling junction reference layer with a fixed magnetic moment vector and a second subsystem for fixing the fixed magnetic moment vector.

3. The magnetoresistive memory element of claim 1, wherein the first magnetic system and the ferromagnetic free layer, which is antiferromagnetically coupled with the tunneling junction free layer, are separated by a first underlayer.

4. The magnetoresistive memory element of claim 3, wherein the ferromagnetic free layer, which is anti-ferromagnetically coupled with the tunneling junction free layer, is sandwiched between the first underlayer and a second underlayer.

5. The magnetoresistive memory element of claim 1, further comprising:
a ferromagnetic offset field layer exhibiting a magnetic moment vector adapted to shift a toggling point for switching of the free magnetic moment vector towards a spin-flop field.

6. The magnetoresistive memory element of claim 2, wherein the ferromagnetic offset field layer is pinned by the second subsystem.

7. The magnetoresistive memory element of claim 5, further comprising:
a multi-purpose layer system arranged adjacent the ferromagnetic offset field layer.

8. The magnetoresistive memory element of claim 7, wherein the ferromagnetic offset field layer is pinned by the multi-purpose layer system.

9. The magnetoresistive memory element of claim 1, wherein a side wall spacer is arranged around at least a part of the perimeter of at least the ferromagnetic tunneling junction free layer.

10. The magnetoresistive memory element of claim 9, wherein a first linear dimension of the tunneling junction free layer in a direction perpendicular to a stacking direction of the stacked structure is less than a second linear dimension of the ferromagnetic free layer, which is anti-ferromagnetically coupled therewith.

11. The magnetoresistive memory element of claim 5, wherein a linear dimension of the tunneling junction free layer in a direction perpendicular to a stacking direction of the stacked structure is less than a second linear dimension of the ferromagnetic offset field layer.

12. The magnetoresistive memory element of claim 5, wherein the ferromagnetic offset field layer is pinned by the second subsystem.

13. The magnetoresistive memory element of claim 5, wherein the ferromagnetic offset field layer is pinned by a multi-purpose layer system.

14. The magnetoresistive memory element of claim 9, wherein a linear dimension of the tunneling junction free layer in a direction perpendicular to a stacking direction of the stacked structure is less than a second linear dimension of a ferromagnetic offset field layer.
